(19) United States
(12) Patent Application Publication
(10) Pub. No.: US 2026/0358731 A1
(43) Pub. Date: Nov. 12, 2026

(54) HEATING HEAD, HEATING DEVICE, AND OPTICAL SYSTEM, IN PARTICULAR EUV LITHOGRAPHY SYSTEM

(71) Applicant: Carl Zeiss SMT GmbH, Oberkochen (DE)

(72) Inventors: Lukas Hege, Neu-Ulm (DE); Christian Muehlke, Oberkochen (DE)

(21) Appl. No.: 19/666,966

(22) Filed: May 4, 2026

Related U.S. Application Data
(63) Continuation of application No. PCT/EP2024/079233, filed on Oct. 16, 2024.

(30) Foreign Application Priority Data
Nov. 13, 2023 (DE) 102023211225.6

(51) Int. Cl. G03F 7/00; G02B 7/18

(52) U.S. Cl. CPC G03F 7/70891; G02B 7/1815

(57) ABSTRACT

The invention relates to a heating head for heating an optical element, comprising: a housing, at least one heating unit, received in the housing, for applying heating radiation to a surface of the optical element (Mi). The heating unit has a heat stop for absorbing scattered radiation. The heat stop comprises at least one aperture for the passage of the heating radiation. The invention also relates to a heating apparatus comprising: at least one heating head which is designed as described above, and at least one heating radiation source for generating heating radiation for the at least one heating unit of the heating head. The invention also relates to an optical system, comprising: an optical element and a heating head for heating the optical element.

### CROSS-REFERENCE TO RELATED APPLICATIONS

This application is a continuation of and claims benefit under 35 U.S.C. § 120 from PCT Application No. PCT/EP 2024/079233, filed on Oct. 16, 2024, which claims the priority of the German patent application DE 10 2023 211 225.6, filed on Nov. 13, 2023. The entire contents of each of these earlier applications are incorporated herein by reference.

### TECHNICAL FIELD

The invention relates to a heating head for heating an optical element, comprising: a housing and at least one heating unit, received in the housing, for applying heating radiation to a surface of the optical element. The invention also relates to a heating apparatus having at least one such heating head and to an optical system, in particular a EUV lithography system, which comprises such a heating apparatus.

### BACKGROUND

In optical systems in the form of lithography systems designed for the EUV wavelength range, in particular in EUV lithography apparatuses, EUV mirrors are typically used as optical elements. The EUV mirrors can, as a result inter alia of absorption of the radiation emitted by an EUV light source, undergo heating and associated thermal expansion or deformation, which can result in impairment of the imaging properties of the optical system, for example the EUV lithography apparatus.

To prevent or at least to reduce surface deformations caused by heat inputs into an EUV mirror, heating apparatuses based on heating radiation, for example in the form of infrared radiation, can be used. With the aid of such a heating apparatus, the EUV mirror can be actively heated in periods in which a comparatively low absorption of EUV radiation takes place, wherein the active heating is scaled back accordingly with increasing absorption of the EUV radiation by the EUV mirror. The EUV mirrors can also be preheated before the actual operation of the EUV lithography system, i.e. before the EUV radiation is applied to the EUV mirrors.

Heating apparatuses or heating heads having heating devices for heating optical elements by application of heating radiation are known from various documents, for example from DE102020213416A1, DE102020207748A1, DE102020207752A1 OR DE102019219289A1.

Heating heads, which are used to heat EUV mirrors, are located under high vacuum, such that heat from a respective heating head or from the mechanical components of a respective heating head may not be dissipated sufficiently via convection. This can have the result that mechanical components such as springs, closures, e.g. bayonets, retaining rings or mounts of the heating heads heat up uncontrollably and their thermal behavior can no longer be controlled. If a predefined maximum temperature is not complied with in the heating head, this can result in an uncontrolled expansion of the material of the mechanical components and, in extreme cases, in a change of their material properties, e.g. if the temperature of the components rises to several hundred degrees Celsius. In the case of uncontrolled expansion of mount components, misalignment and, in the worst case, damage to the optical elements of the heating head can occur.

### SUMMARY

A general aspect of the invention is to provide a thermally stabilized heating head, and also a heating apparatus and an optical system comprising such a heating head.

This general aspect is achieved by a heating head of the type mentioned in the introduction, wherein the heating unit has at least one heat stop for absorbing scattered radiation, wherein the heat stop comprises at least one aperture for the passage of the heating radiation.

The inventors have recognized that the uncontrolled heating of mechanical components can essentially be attributed to scattered radiation, which can arise, for example, after passing through a structured optical element in a respective heating unit. Due to the scattered radiation, in particular mechanical components such as mount components, e.g. in the form of springs, closures, e.g. bayonets, retaining rings, etc., can expand and, as described above, may change their material properties under extreme loading. In particular, the uncontrolled expansion of mount components, which can be attributed to the heating by the scattered radiation, can result in the above-described misalignment or possibly in damage to the mounted optical elements.

The heat stop is used to absorb the scattered radiation and dissipates the heat received during absorption in a defined manner. The heat, which without the presence of the heat stop would be absorbed at critical points, e.g. at mount components, within the heating head, can be guided to non-critical points within the heating head with the aid of the heat stop and therefore contribute to the thermal stabilization of the heating head. The heat stop shades in particular the mechanical components of the heating head that are relevant with regard to the uncontrolled thermal expansion. The heat stop can therefore prevent uncontrolled heating of mechanical components of the heating head.

In one embodiment, the heating unit has, in the beam path of the heating radiation upstream of the heat stop, at least one optical element creating the scattered radiation. The scattered radiation is typically generated when the heating radiation passes through a transmitting optical element, more specifically when it passes through not completely smooth surfaces of the transmitting optical element. It is also possible for the scattered radiation to be generated when the heating radiation is reflected on a reflective optical element of the heating unit, for example on a mirror which has a not completely smooth surface.

In a development, the optical element creating the scattered radiation is designed as a structured optical element, in particular as a Fresnel lens or as a Fresnel lens arrangement. The structured optical element may be part of a collimator which is used to collimate the heating radiation when it exits a fiber connector which is used to connect the heating unit to one or more light guiding fibers (see below). The structured optical element may, for example, be a Fresnel lens which has one or optionally two structured surfaces. However, it may also be a Fresnel lens arrangement which has a plurality of Fresnel lenses. The Fresnel lenses of the lens arrangement may be in the form of a plurality of individual lenses, which form a Fresnel lens array. However, the Fresnel lens arrangement may also be an individual optical element, which, for example, has multiple structured segments each in the form of a Fresnel lens. The structured optical element does not necessarily have to be a Fresnel lens or a Fresnel lens arrangement, it may also be another type of structured optical element, for example a diffractive optical element.

In a further embodiment, an edge of the aperture is arranged outside a beam path of the heating radiation. The heat stop is typically not used as an aperture stop to delimit the edge of the beam path of the heating radiation, but rather only to absorb scattered radiation that spreads outside the beam path of the heating radiation. To prevent the edge of the heat stop from being a light-delimiting edge during the thermal expansion, the edge of the heat stop has a safety distance from the outer circumference of the beam path. The distance is dimensioned in such a way that the heat stop does not expand so far that the edge of the aperture of the heat stop reaches the outer circumference of the beam path of the heating radiation, even under the maximum thermal load impinging on it and thus at its maximum operating temperature. The safety distance may, for example, be set in the manner described in DE102020208007A1, which is incorporated by reference in its entirety into the content of this application.

In a further embodiment, the heat stop is designed to at least partially shade at least one mount component of the heating unit. In order to shield the mount component or components from scattered radiation as efficiently as possible, it is advantageous if the heat stop is positioned in the vicinity of the mount component or components to be shielded. It goes without saying that the heat stop may also be designed to at least partially shade mechanical elements of the heating unit other than mount components.

In a further embodiment, the heat stop and/or the housing are/is formed from a metallic material, in particular from high-grade steel or from copper. Metallic materials usually have a high thermal conductivity, which lies in the order of about 10 W/(mK) or higher. The use of material with good thermal conductivity for the heat stop and for the housing is advantageous in order to efficiently dissipate heat. In order to dissipate the heat from the heating head, the heating head, more specifically the housing of the heating head, may be connected to a heat sink. The heat sink may, for example, be a supporting frame or the like, to which the heating head is fastened.

In a further development, the heat stop has at least one ventilation opening which is arranged outside the beam path of the heating radiation. In this case, the heating head is typically located in an environment which is evacuated before operation of the optical system. The ventilation opening is used to generate an air flow during evacuation that is guided past the optical elements of the heating unit in order to as much as possible avoid the accumulation of particles on the optical elements of the heating unit.

In a further embodiment, the heat stop is mounted on the housing via a heat-conducting connection. For efficient dissipation of the heat received by the heat stop, a satisfactorily heat-conducting connection of the heat stop to the housing and/or to other mechanical components of the heating head is advantageous. A heat-conducting connection can be produced in different ways.

In a development of this embodiment, the heat-conducting connection is produced by a screw fitting or by an adhesive bond. If the heat-conducting connection is realized by a screw fitting, it is advantageous if the respective screw connections are realized with a high surface pressure. To improve heat conduction, the number of screw connections by which the heat stop is mounted on the housing may be increased. An adhesive bond also makes it possible to realize a satisfactorily heat-conducting connection of the stop to the housing and/or to other mechanical components. The housing may be designed in one part or multiple parts.

In one embodiment, the housing has a first housing part and a second housing part and the heat stop is mounted between the two housing parts. The heat stop may in particular be clamped between the two housing parts if the two housing parts are connected to one another via a screw fitting. Mounts for the optical elements of the heating unit may be received in the first housing part and/or in the second housing part.

In a further embodiment, the heating unit has a polarization beam splitter for dividing the heating radiation into two differently polarized heating radiation components. With the aid of a heating unit which has a polarization beam splitter for dividing the heating radiation into two differently polarized heating radiation components, the two heating radiation components can—usually with the additional use of (at least) one polarization modulator—be polarized parallel to the plane of incidence of the heating radiation on the surface of the optical element (p-polarization). With a suitable choice of the angle of incidence, typically close to the Brewster angle, the reflectivity of the surface for the heating radiation can be significantly reduced, as described, for example, in DE102020213416 A1 cited in the introduction.

In a development of this embodiment, the heat stop is arranged in the beam path of the heating radiation downstream of the polarization beam splitter and has two apertures for the passage in each case of one of the two heating radiation components of the heating radiation. It has been shown that it is advantageous for the thermal stabilization of the heating head if the—usually one-part—heat stop is arranged in the beam path downstream of the polarization beam splitter and has two apertures for in each case one of the two heating radiation components. Instead of a common heat stop for the two heating radiation components, it is fundamentally also possible to use two heat stops which each have an aperture for the passage of a respective heating radiation component.

In a further embodiment, the heating head has at least one fiber connector for connecting the heating unit to at least one light guiding fiber. Typically, the heating radiation is supplied to the heating head via one or more light guiding fibers. A separate fiber connector may be provided for each light guiding fiber, but it is also possible for multiple, in particular all of the light guiding fibers of the heating unit to be connected to the heating head via a common fiber connector. A light guiding fiber is typically used to supply the heating radiation from a heating radiation source which is assigned to the respective light guiding fiber. The heating radiation typically exits an outlet-side end of the or a respective light guiding fiber and is guided with free-space propagation in the heating unit. The light guiding fiber is an optical fiber designed to guide the heating radiation from the heating radiation source to the fiber connector of the heating head. Instead of light guiding fibers, other types of optical waveguides may optionally also be used to supply the heating radiation to the heating head.

A further aspect of the invention relates to a heating apparatus comprising: at least one heating head, which is designed as described above, and at least one heating radiation source which is designed to generate heating radiation for the at least one heating unit of the heating head. The heating radiation source is typically an IR emitter, for example an IR laser or an IR LED. To generate a desired heating radiation profile on the surface of the optical element, the heating radiation source(s) assigned to a respective heating unit can be activated or deactivated in a targeted manner. The heating apparatus may in particular have multiple heating heads. As is described in DE 102020207748 A1 cited above, the use of two or more separate heating heads makes it possible to for example realize “crossing” radiation input coupling of the heating radiation generated by the heating heads into the optical element. However, such radiation input coupling of the heating radiation is not mandatory.

A further aspect of the invention relates to an optical system, in particular a EUV lithography system, comprising: at least one optical element, in particular a mirror, and a heating apparatus for heating the optical element, which is designed as described above. The EUV lithography system can be an EUV lithography apparatus for exposing a wafer, or can be some other optical arrangement that uses EUV radiation, for example an EUV inspection system, for example for inspecting masks, wafers or the like that are used in EUV lithography. It goes without saying that a plurality of heating apparatuses may be arranged in the optical system, each of which is designed to heat an optical element. The optical system does not necessarily have to be an EUV lithography system, it may for example be a DUV lithography system or another type of optical system.

The heating head or heating heads may be oriented such that the heating radiation is incident on the surface of the optical element at an angle of incidence that lies in the region of the Brewster angle. This makes it possible for as large a proportion of the heating radiation as possible to be absorbed by the optical element, as is described in relation to the heating units in DE102020213416A1 cited above.

Further features and advantages of the invention are evident from the following description of exemplary embodiments of the invention with reference to the figures of the drawing, which show details essential to the invention, and from the claims. The individual features may each be implemented individually on their own or as a plurality in any desired combination in a variant of the invention.

### BRIEF DESCRIPTION OF DRAWINGS

Exemplary embodiments are illustrated in the schematic drawing and are explained in the description that follows. In the figures:

FIG. 1 schematically shows a meridional section through a projection exposure apparatus for EUV projection lithography,

FIG. 2 shows a schematic illustration of an optical element in the form of an EUV mirror and a heating apparatus having two heating heads for applying heating radiation to a surface of the optical element,

FIG. 3 shows a schematic illustration of a heating head having a heating unit which has a heat stop, and

FIG. 4 shows a schematic illustration of a top view of the heat stop from FIG. 3.

### DETAILED DESCRIPTION

In the description of the drawings that follows, identical reference signs are used for identical or functionally identical components.

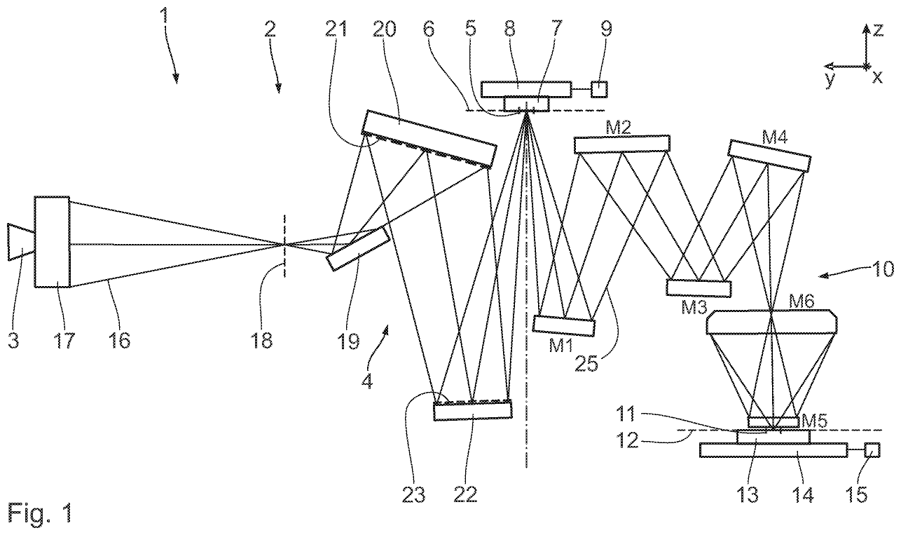

The essential constituent parts of an optical arrangement for EUV lithography in the form of a microlithographic projection exposure apparatus 1 are described by way of example below with reference to FIG. 1. The description of the basic setup of the projection exposure apparatus 1 and the constituent parts thereof should not be understood to have a limiting effect.

One embodiment of an illumination system 2 of the projection exposure apparatus 1 has, in addition to a light or radiation source 3, an illumination optics unit 4 for illuminating an object field 5 in an object plane 6. In an alternative embodiment, the light source 3 may also be provided in the form of a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable, in particular in a scanning direction, by way of a reticle displacement drive 9.

FIG. 1 shows a Cartesian xyz-coordinate system for explanatory purposes. The x-direction runs perpendicularly to the plane of the drawing into the latter. The y-direction runs horizontally, and the z-direction runs vertically. The scanning direction runs along the y-direction in FIG. 1. The z-direction runs perpendicularly to the object plane 6.

The projection exposure apparatus 1 comprises a projection system 10. The projection system 10 is used to image the object field 5 into an image field 11 in an image plane 12. A structure on the reticle 7 is imaged onto a light-sensitive layer of a wafer 13 that is arranged in the region of the image field 11 in the image plane 12. The wafer 13 is held by a wafer holder 14. The wafer holder 14 is displaceable, in particular in the y-direction, by way of a wafer displacement drive 15. The displacement, firstly, of the reticle 7 by way of the reticle displacement drive 9 and, secondly, of the wafer 13 by way of the wafer displacement drive 15 can be synchronized with one another.

The radiation source 3 is an EUV radiation source. The radiation source 3 emits, in particular, EUV radiation 16, which is also referred to below as used radiation, illumination radiation or illumination light. The used radiation has in particular a wavelength in the range between 5 nm and 30 nm. The radiation source 3 may be a plasma source, for example a laser-produced plasma (LPP) source or a gas discharge-produced plasma (GDPP) source. It may also be a synchrotron-based radiation source. The radiation source 3 may be a free electron laser (FEL).

The illumination radiation 16 emanating from the radiation source 3 is focused by a collector mirror 17. The collector mirror 17 may be a collector mirror with one or more ellipsoidal and/or hyperboloidal reflection surfaces. The illumination radiation 16 may be incident on the at least one reflection surface of the collector mirror 17 with grazing incidence (GI), i.e. at angles of incidence of greater than 45°, or with normal incidence (NI), i.e. at angles of incidence of less than 45°. The collector mirror 17 may be structured and/or coated, firstly to optimize its reflectivity for the used radiation and secondly to suppress extraneous light.

Downstream of the collector mirror 17, the illumination radiation 16 propagates through an intermediate focus in an intermediate focal plane 18. The intermediate focal plane 18 may constitute a separation between a radiation source module, having the radiation source 3 and the collector mirror 17, and the illumination optics unit 4.

The illumination optics unit 4 comprises a deflection mirror 19 and, disposed downstream thereof in the beam path, a first facet mirror 20. The deflection mirror 19 may be a planar deflection mirror or alternatively a mirror with a beam-influencing effect that goes beyond the pure deflection effect. Alternatively or additionally, the deflection mirror 19 can be designed as a spectral filter that separates a used light wavelength of the illumination radiation 16 from extraneous light having a wavelength that deviates therefrom. The first facet mirror 20 comprises a multiplicity of individual first facets 21, which are also referred to below as field facets. FIG. 1 illustrates only some of these facets 21 by way of example. In the beam path of the illumination optics unit 4, a second facet mirror 22 is disposed downstream of the first facet mirror 20. The second facet mirror 22 comprises a plurality of second facets 23.

The illumination optics unit 4 thus forms a doubly faceted system. This basic principle is also referred to as a fly's eye integrator. The second facet mirror 22 is used to image the individual first facets 21 into the object field 5. The second facet mirror 22 is the last beam-shaping mirror or else actually the last mirror for the illumination radiation 16 in the beam path upstream of the object field 5.

The projection system 10 comprises a plurality of mirrors Mi, which are consecutively numbered in accordance with their arrangement in the beam path of the projection exposure apparatus 1.

In the example illustrated in FIG. 1, the projection system 10 comprises six mirrors M1 to M6. Alternatives with four, eight, ten, twelve or any other number of mirrors Mi are likewise possible. The penultimate mirror M5 and the last mirror M6 each have a through opening for the illumination radiation 16. The projection system 10 is a doubly obscured optics unit. The projection optics unit 10 has an image-side numerical aperture which is greater than 0.4 or 0.5 and which may also be greater than 0.6 and which may be for example 0.7 or 0.75.

Just like the mirrors of the illumination optics unit 4, the mirrors Mi may have a highly reflective coating for the illumination radiation 16.

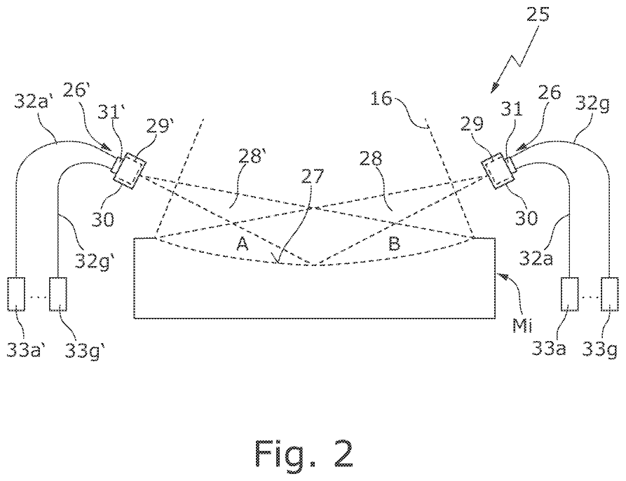

It can be advantageous if individual or possibly all mirrors Mi of the projection optics 10 are heated. FIG. 2 shows, in highly schematic form, a mirror Mi to be heated of the projection optics 10 and a heating apparatus 25 which is used to heat the mirror Mi. For the heating of the mirror Mi, the heating apparatus 25 has a heating head 26 and a further heating head 26'. In the example shown, the two heating heads 26, 26′ are of identical construction and arranged on opposite sides of the mirror Mi. The mirror Mi comprises an optical surface 27, on which the EUV radiation 16 is incident.

The heating head 26 emits heating radiation 28 which is incident in the form of a beam on a first subregion, denoted by “A” in FIG. 2, of the optical surface 27 of the mirror Mi, which faces toward the further heating head 26′. Accordingly, the further heating head 26′ emits heating radiation 28′, which is irradiated in the form of a beam onto a second subregion, denoted by “B” in FIG. 2, of the optical surface 27 of the mirror Mi, which faces toward the heating head 26. The beams of the heating radiation of the two heating heads 26, 26′ overlap or cross one another on their way to the optical surface 27. It goes without saying that more than two heating heads 26, 26′, . . . for applying heating radiation 28, 28′, . . . to the optical surface 27 of the mirror Mi can also be used, for example three heating heads arranged in a regular arrangement around the mirror Mi, as is the case with the heating units described in DE102020207748A1.

The two heating heads 26, 26′ of the heating apparatus 25 described in the present case each have a heating unit 29, 29′, which is integrated or arranged in a housing 30, 30′ of the respective heating head 26, 26′. In principle, it is also possible for two or more heating units to be provided in a respective housing 30, 30′.

The heating units 29, 29′ of the heating heads 26, 26′ are connected via a respective fiber connector 31, 31′, which is mounted on the housing 30, 30′ of the respective heating head 26, 26′, via a number of, in the example shown, seven light guiding fibers 32a to 32g, 32a′ to 32g′ to a respective heating radiation source 33a to 33g, 33a′ to 33g'. The heating radiation source 33a to 33g, 33a′ to 33g', which is assigned to a respective light guiding fiber 32a to 32g, 32a′ to 32g′ of one of the heating units 29, 29', can be activated or deactivated with the aid of a control device (not illustrated diagrammatically) in order to generate different heating radiation profiles on the optical surface 27 of the mirror Mi. In the example shown, the heating radiation sources 33a to 33g, 33a′ to 33g′ are IR emitters, for example IR lasers or IR LEDs, which are designed to generate heating radiation in the near-infrared wavelength range.

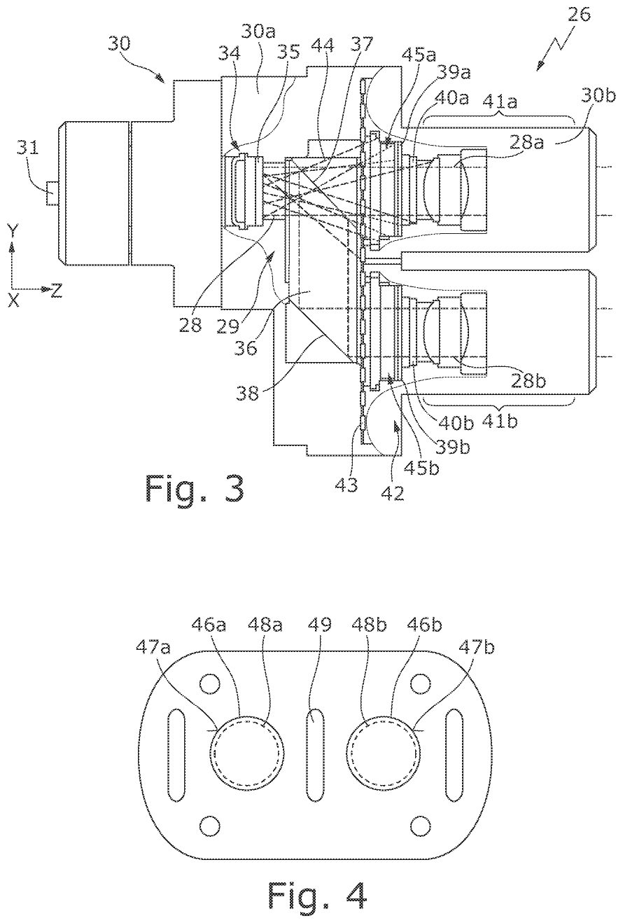

FIG. 3 shows the heating head 26 from FIG. 2 with the heating unit 29 in a sectional illustration. The heating radiation 28 generated by the heating radiation sources 33a to 33g and guided by the light guiding fibers 32a to 32g to the heating head 26 (see FIG. 2) exits the fiber ends of the light guiding fibers 32a to 32g in the housing 30. The heating radiation 28 exiting the fiber ends is guided with free-space propagation via common optics in the heating unit 29. The heating radiation 28 first passes through an optical collimator 34, which can have one or more lenses. In the example shown, the collimator 34 has, as the last optical element thereof in the beam path, a Fresnel lens arrangement 35, but the Fresnel lens arrangement 35 does not necessarily have to form the last optical element of the collimator 34. In the example shown, the Fresnel lens arrangement 35 has a plate-like main body, the surface of which has seven sectors each structured in the form of a Fresnel lens. The heating radiation 28 emitted by one of the light guiding fibers 32a to 32g is incident in each of the sectors and is collimated by the respective Fresnel lens. It goes without saying that the Fresnel lens arrangement 35 may also be designed in other ways, for example in the form of a Fresnel lens array or the like.

The heating radiation 28 exiting the collimator 34 then enters an optical component 36. The fiber end or the position of the heating unit 29 relative to the fiber end may optionally be adjustable both laterally (within the xy-plane of the coordinate system illustrated in the region of the fiber end) and axially (in the z-direction of this coordinate system).

The optical component 36, which in the example shown consists of quartz glass, is used to divide the heating radiation 28 into two linearly polarized heating radiation components 28a, 28b and for this purpose has a polarization beam splitter 37. The first heating radiation component 28a is transmitted by the polarization beam splitter 37 and retains the original propagation direction. The second heating radiation component 28b is deflected or reflected at the polarization beam splitter 37 by 90° within the optical component 36 and is incident on a planar deflection surface 38 which, by total internal reflection, deflects or reflects approximately the entire power of the second heating radiation component 28b again by 90°.

As can also be seen in FIG. 3, the first heating radiation component 28a and the second heating radiation component 28b exit the optical component 36 in parallel in an offset manner. A respective heating radiation component 28a, b passes successively through an optical retarder 39a and 39b, a beam shaping device 40a and 40b in the form of a diffractive optical element and an optical telescope 41a and 41b, respectively. After passing through the respective optical telescope 41a and 41b, the two heating radiation components 28a, 28b exit the heating head 26 in a laterally offset manner and together form the heating radiation 28 which is applied to the surface 27 of the mirror Mi.

Via the two optical retarders 39a and 39b, which can be designed, for example, as λ/2 plates, a setting of the respective polarization direction of the two heating radiation components 28a, b can be achieved. The two diffractive optical elements are used as beam shaping units 40a and 40b to impose an individual heating radiation profile (intensity profile) on the surface 27 of the mirror Mi to be heated by use of beam shaping. In the example shown, the heating radiation profile is in each case a top hat profile. The diffractive optical element 40b, which is passed through by the second heating radiation component 28b, may be rotatably mounted for adjustment purposes, but this is not mandatory.

The optical telescopes 41a and 41b are each constructed from multiple lenses in FIG. 3, two of which are diagrammatically illustrated. The optical telescopes 41a and 41b are used to provide a suitable additional beam deflection or beam expansion before the heating radiation 28 is applied to the surface 27 of the mirror Mi.

The above-described generation of two in each case linearly polarized heating radiation components 28a,b makes it possible for the polarization direction of the heating radiation 28, which is unpolarized when entering the heating unit 29, to be oriented in a manner polarized parallel to a plane of incidence (not diagrammatically illustrated) on the surface 27 of the mirror Mi when said radiation exits the heating unit 29. With a suitable choice of the angle of incidence in the region of the Brewster angle, it is in this way possible for the reflection of the heating radiation 28 on the surface 27 of the mirror Mi to be minimized and the absorption of the heating radiation 28 to be maximized.

In the example shown, the housing 30 of the heating head 26 has two housing parts 30a, 30b, which are connected to one another or fastened to one another via a screw fitting 42, which has a plurality of screw connections. Arranged between the two housing parts 30a, 30b is a heat stop 43 which is firmly clamped or fixed between the housing parts 30a, 30b via the screw fitting. The screw fitting 42 realizes a surface pressure on the heat stop 43 that produces a heat-conducting connection between the heat stop 43 and the housing 30. This is advantageous for efficiently dissipating heat from the heat stop 43 and transporting it via the housing 30 to a heat sink (not diagrammatically illustrated), which may, for example, be a supporting structure on which the heating head 26 is held or a cooling element which is in contact with the outer side of the housing 30. It is also possible to actively cool the heating head 26 by introducing into the housing 30 cooling channels through which a cooling fluid, for example water, flows. In the example shown, both the housing parts 30a, 30b and the heat stop 43 are produced from a metallic material, namely high-grade steel.

The heat stop 43 illustrated in dashed lines in FIG. 3 is used to absorb scattered radiation 44, which is illustrated in dash-dotted lines in FIG. 3 and generated by the Fresnel lens arrangement 35. The heat stop 43 absorbs the scattered radiation 44, with the result that it cannot reach mount components 45a arranged in the beam path downstream of the heat stop 43. The mount components 45a (not illustrated in detail) may, for example, be closures, springs, retaining rings, etc. FIG. 3 illustrates in dotted lines the scattered radiation that would be incident on the mount components 45a without the provision of the heat stop 43.

For efficient shading of the mount components 45a on which the scattered radiation 44 should not be incident, it is advantageous if the heat stop 43 is positioned as close as possible to the mount components 45a. Via the polarization beam splitter 37, a portion of the scattered radiation 44 is deflected and can therefore also reach mount components 45b of the optical elements 39b, 40b, 41b, which are arranged in the beam path of the second heating radiation component 28b. These mount components 45b can also be protected against the scattered radiation 44 with the aid of the heat stop 43.

The heat stop 43 illustrated in a top view in FIG. 4 has, in the example shown, two apertures 46a, 46b which are used for the passage of the first heating radiation component 28a and of the second heating radiation component 28b, respectively. As can also be seen in FIG. 4, an annularly circumferential edge 47a, 47b of the respective aperture 46a, 46b is spaced apart from the beam path 48a, 48b, more specifically from the outer periphery of the beam path 48a, 48b of the respective heating radiation component 28a, 28b. This ensures that the heat stop 43 is used only to dissipate heat and does not assume any optical function. Instead of the one-part heat stop 43 shown in FIG. 4, it is optionally also possible to use two heat stops to absorb the scattered radiation 44 of the first heating radiation component 28a and of the second heating radiation component 28b.

In addition to the two apertures 46a, 46b, the heat stop 43 has further openings which are used for the passage of screws in order to fix the heat stop 43 between the two housing parts 30a, 30b. The heat stop 43 also has ventilation openings 49, which deflect the air flow during evacuation of the lithography system 1 or of the heating head 26 in a desired manner. It goes without saying that the arrangement and the geometry of the ventilation openings 49 can deviate from the illustration in FIG. 4.

It also goes without saying that the heating unit 29 does not necessarily have to be designed in the manner described here, but rather can also be designed in other ways. For example, the heating unit 29 may not have a polarization beam splitter 37 to divide the heating radiation 28 into two heating radiation components 28a, b. In this case, the components of the heating unit 29 that are required for the beam guidance of the second heating radiation component 28b are omitted. In addition, the optical retarder 39a can also be omitted, since the heating radiation 28 in this case exits the heating unit 29 unpolarized. In this case, the heating radiation 28 can be irradiated substantially perpendicularly to the surface 27 of the mirror Mi, i.e. it is not necessary to irradiate the heating radiation 28 onto the surface 27 at an angle of incidence which corresponds substantially to the Brewster angle. In this case, the heating unit 29 or multiple heating units 29 may also be accommodated in the housing 30. Possible other configurations of the heating unit 29 are described, for example, in DE102020213416A1 cited above, in DE102020207748A1 or in DE102020207752A1, each of which are incorporated by reference in their entirety into the content of this application.

What is claimed is:

1. A heating head for heating an optical element, comprising:
a housing,
at least one heating unit, received in the housing, for applying heating radiation to a surface of the optical element,
wherein the heating unit has a heat stop for absorbing scattered radiation, wherein the heat stop comprises at least one aperture for the passage of the heating radiation, and wherein the heat stop is designed to at least partially shade at least one mount component of the heating unit).

2. The heating head as claimed in claim 1, wherein the heating unit has, in the beam path of the heating radiation upstream of the heat stop, at least one optical element generating the scattered radiation.

3. The heating head as claimed in claim 2, wherein the optical element generating the scattered radiation is designed as a structured optical element, in particular as a Fresnel lens or as a Fresnel lens arrangement.

4. The heating head as claimed in claim 1, wherein an edge of the aperture is arranged outside the beam path of the heating radiation.

5. The heating head as claimed in claim 1, wherein the heat stop and/or the housing is formed from a metallic material, in particular from high-grade steel or from copper.

6. The heating head as claimed in claim 1, wherein the heat stop has at least one ventilation opening which is arranged outside the beam path of the heating radiation.

7. The heating head as claimed in claim 1, wherein the heat stop is mounted on the housing via a heat-conducting connection.

8. The heating head as claimed in claim 7, wherein the heat-conducting connection is produced by a screw fitting or by an adhesive bond.

9. The heating head as claimed in claim 1, wherein the housing has a first housing part and a second housing part and the heat stop is mounted between the two housing parts.

10. The heating head as claimed in claim 1, wherein the heating unit has a polarization beam splitter for dividing the heating radiation into two differently polarized heating radiation components.

11. The heating head as claimed in claim 10, wherein the heat stop is arranged in the beam path of the heating radiation downstream of the polarization beam splitter and has two apertures for the passage in each case of one of the two heating radiation components.

12. The heating head as claimed in claim 1, further comprising: at least one fiber connector for connecting the heating unit to at least one light guiding fiber.

13. A heating apparatus comprising:
at least one heating head as claimed in claim 1, and
at least one heating radiation source, which is designed to generate heating radiation for the at least one heating unit of the heating head.

14. An optical system, in particular an EUV lithography system, comprising:
an optical element, in particular a mirror, and
a heating apparatus as claimed in claim 13 for heating the optical element.
